(19) United States
(12) Patent Application Publication
(10) Pub. No.: US 2014/0152401 A1
(43) Pub. Date: Jun. 5, 2014

(54) Resonant Circuit with Improved Capacitor Quality Factor

(71) Applicant: SPACE SYSTEMS/LORAL, LLC, Palo Alto, CA (US)

(72) Inventors: Slawomir J. Fiedziuszko, Palo Alto, CA (US); Stephen D. Berry, San Ramon, CA (US)

(73) Assignee: Space Systems/Loral, LLC, Palo Alto, CA (US)

(21) Appl. No.: 13/692,551

(22) Filed: Dec. 3, 2012

(51) Int. Cl. H03H 7/01

(52) U.S. Cl. CPC H03H 7/0115
USPC 333/174

(57) ABSTRACT

A resonant circuit, configured to operate at a resonant frequency, includes a first arrangement providing a first equivalent capacitance ‘C’ and a second arrangement providing a first inductance. The first arrangement includes a quantity of ‘n’ capacitive elements connected in parallel, n being at least two, each of the n capacitive elements having a nominal capacitance approximately equal to C/n. The resonant frequency may exceed 1 GHz, the first equivalent capacitance may be at least 3 pF, and a composite Q factor of the first arrangement may be greater than 800. Whereas a single capacitive element having a capacitance of C may exhibit a Q factor equal to ‘Q1’, the composite Q factor of the first arrangement may be equal to ‘Q2’ where Q2 is substantially higher than Q1.

### TECHNICAL FIELD

This invention relates generally to a resonant circuit, and particularly to a resonant circuit for a radio frequency (RF) filter having a capacitor with improved quality factor, ‘Q’.

### BACKGROUND

The assignee of the present invention manufactures and deploys spacecraft for, inter alia, communications and broadcast services from geosynchronous orbit. A substantial number of radio frequency (RF) filters are required in such spacecraft. For example, a satellite input multiplexer may utilize a number of such filters, each filter having the functionality of separating and isolating a specific respective signal or bandwidth frequency from a broadband uplink signal received by a spacecraft antenna.

RF filters of concern to the present inventors include resonant circuits having capacitive and inductive elements. Referring now to FIG. 1 capacitive element 101 may be disposed in parallel with inductive element 102 as illustrated by example arrangement 100. Alternatively, capacitive element 101 may be disposed in series with inductive element 102 as illustrated by example arrangement 150. Capacitive element 101 may be, as shown, a variable capacitor (which may be referred to as a varactor diode, or varactor). Alternatively, capacitive element may be a fixed capacitor.

The so-called “Quality Factor” (or Q) of a resonant circuit is proportional to the ratio of the average stored energy over the energy loss in the circuit. Thus, it is a measure of power loss of the resonant circuit where higher Q indicates lower loss. The relationship between power loss and Q value as a function of frequency for a resonant circuit having a center frequency of 4 GHz is illustrated in FIG. 2.

RF and microwave components with high Q are always desired in the design of devices and systems for RF, microwave and millimeter wave applications. For example, high Q resonator or lumped element components (capacitors, inductors) are desired to build high Q filters, and a strong need exists for resonant circuits with improved (high) quality factor −Q.

### SUMMARY OF INVENTION

The present inventors have appreciated that, for a resonant circuit requiring a specified capacitance, the specified capacitance is advantageously provided by two or more capacitive elements in parallel. Such an arrangement, as described in greater detail hereinbelow, has been found to exhibit a superior composite Q factor than can be achieved by a single capacitive element providing the specified capacitance.

In an embodiment, a resonant circuit, configured to operate at a resonant frequency, includes a first arrangement providing a first equivalent capacitance ‘C’ and a second arrangement providing a first inductance. The first arrangement includes a quantity of ‘n’ capacitive elements connected in parallel, n being at least two, each of the n capacitive elements having a nominal capacitance approximately equal to C/n.

In a further embodiment at least one of the n capacitive elements may have a fixed capacitance. At least one of the n capacitive elements may have a variable capacitance.

In another embodiment, the resonant frequency may be at least 1 GHz, the first equivalent capacitance may be at least 3 pF, and a composite Q factor of the first arrangement may be greater than 800. The first arrangement may be connected in parallel with the second arrangement. The first arrangement may be connected in series with the second arrangement. At least one capacitive element may be a varactor.

In yet another embodiment, the resonant frequency may be at least 1 GHz, the first equivalent capacitance may be at least 12 pF, and a composite Q factor of the first arrangement may be greater than 300.

In an embodiment, a single capacitive element has a capacitance of C and exhibits a Q factor equal to ‘Q1’, the composite Q factor of the first arrangement is equal to ‘Q2’, and Q2 is substantially higher than Q1.

In an embodiment a resonant circuit, configured to operate at a resonant frequency, includes a first arrangement providing a first capacitance and a second arrangement providing a first inductance. The resonant frequency is at least 1 GHz, the first capacitance is at least 3 pF, and a composite Q factor of the first arrangement is greater than 800. The first arrangement may include a quantity of ‘n’ capacitive elements connected in parallel, n being at least two, each of the n capacitive elements having a nominal capacitance approximately equal to C/n.

In an embodiment, a resonant circuit, configured to operate at a resonant frequency, includes a first arrangement providing a first equivalent capacitance ‘C’ and a second arrangement providing a first inductance. The first arrangement includes a quantity of ‘n’ capacitive elements connected in parallel, n being at least two, each of the n capacitive elements having a nominal capacitance approximately equal to C/n. A single capacitive element having a capacitance of C exhibits a Q factor equal to ‘Q1’, the composite Q factor of the first arrangement is equal to ‘Q2’, and Q2 is substantially higher than Q1.

### BRIEF DESCRIPTION OF THE DRAWINGS

The included drawings are for illustrative purposes and serve only to provide examples of possible structures for the disclosed inventive filters and multiplexers. These drawings in no way limit any changes in form and detail that may be made by one skilled in the art without departing from the spirit and scope of the disclosed embodiments.

FIG. 1 shows examples of resonant circuits of the prior art.

FIG. 2 illustrates quality factor of a resonant circuit as a function of frequency.

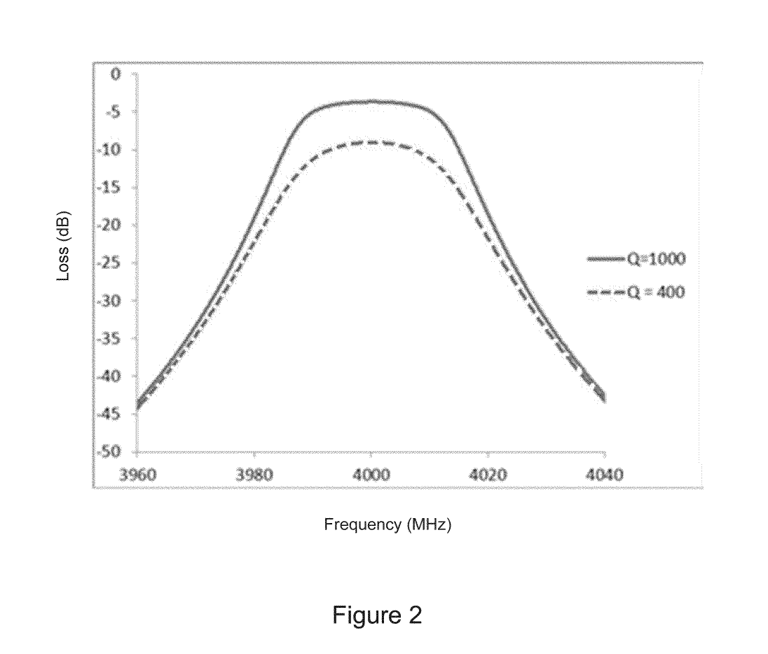

FIG. 3 shows an example of a circuit diagram of a resonant circuit in accordance with an embodiment.

FIG. 4 illustrates a plot of quality factor as a function of capacitance.

Throughout the drawings, the same reference numerals and characters, unless otherwise stated, are used to denote like features, elements, components, or portions of the illustrated embodiments. Moreover, while the subject invention will now be described in detail with reference to the drawings, the description is done in connection with the illustrative embodiments. It is intended that changes and modifications can be made to the described embodiments without departing from the true scope and spirit of the disclosed subject matter, as defined by the appended claims.

### DETAILED DESCRIPTION

Specific exemplary embodiments of the invention will now be described with reference to the accompanying drawings. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “connected” or “coupled” to another element, it can be directly connected or coupled to the other element, or intervening elements may be present. Furthermore, “connected” or “coupled” as used herein may include wirelessly connected or coupled. It will be understood that although the terms “first” and “second” are used herein to describe various elements, these elements should not be limited by these terms. These terms are used only to distinguish one element from another element. As used herein, the term “and/or” includes any and all combinations of one or more of the associated listed items. The symbol “/” is also used as a shorthand notation for “and/or”.

The terms “spacecraft”, “satellite” may be used interchangeably herein, and generally refer to any orbiting satellite or spacecraft system.

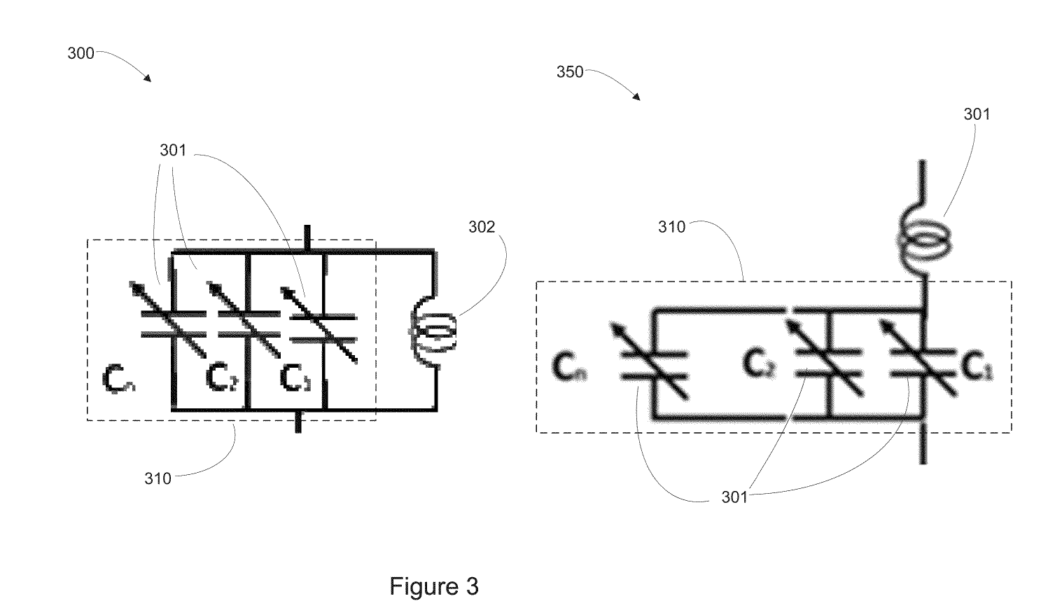

Presently disclosed is a resonant circuit including a first arrangement having a first effective capacitance, ‘c’, and a second arrangement having a first inductance, the first capacitance being provided by at least two capacitive elements connected in parallel. Referring now to FIG. 3, resonant circuit 300 may include first arrangement 310, having the first capacitance. In the illustrated example, arrangement 310 includes three parallel variable capacitors 301. However, arrangements of two, four or more capacitive elements are also within the contemplation of the present disclosure. Moreover, although variable capacitors 301 are illustrated in FIG. 3, one, more, or all capacitive elements may be fixed capacitors.

Advantageously, each capacitive element may have a nominal capacitance that is approximately c/3. More generally, the nominal capacitance of each capacitive element is, advantageously, n/3, where ‘n’ represents the number of capacitive elements connected in parallel.

Advantageously, variable capacitor 301 may be a voltage tunable varactor. In an embodiment, the voltage tunable varactor may be a hyperabrupt junction gallium arsenide diode such as the MA46410 thru MA46480 series of varactors diodes available from M/A-COM Technology Solutions, Inc., of Lowell Mass.

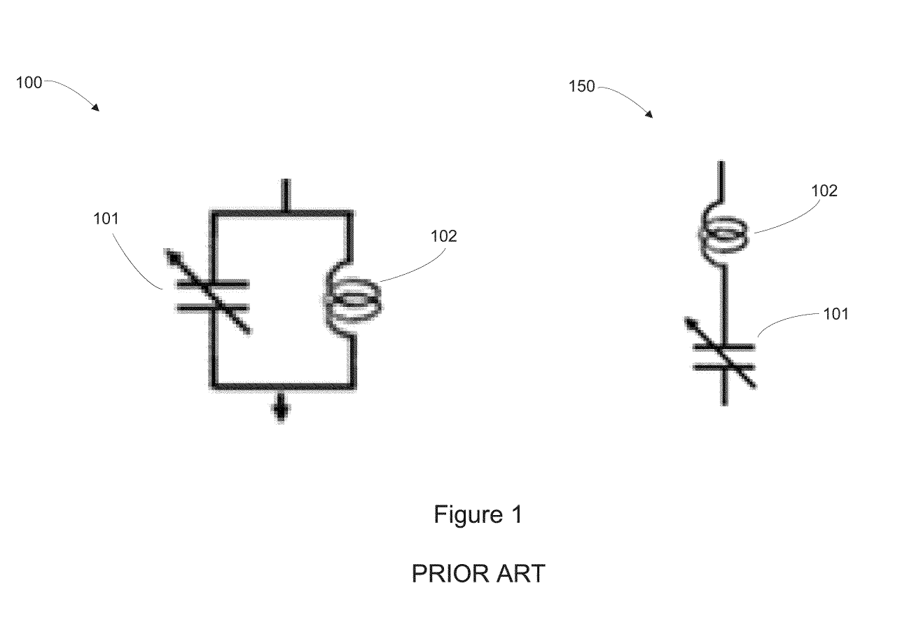

The present inventors have appreciated that, where capacitive arrangement is 310 is required to provide an equivalent capacitance ‘C’, the effective capacitance ‘C’ may be advantageously provided by disposing two or more capacitive elements connected in parallel, each individual capacitive element having a nominal capacitance approximately equal to C/n. For example, if we assume that in the resonant circuits of FIG. 1 capacitive arrangement 310 is required to provide a nominal capacitance of 3 pF, each capacitive element 301 may have a capacitance of 1 pF.

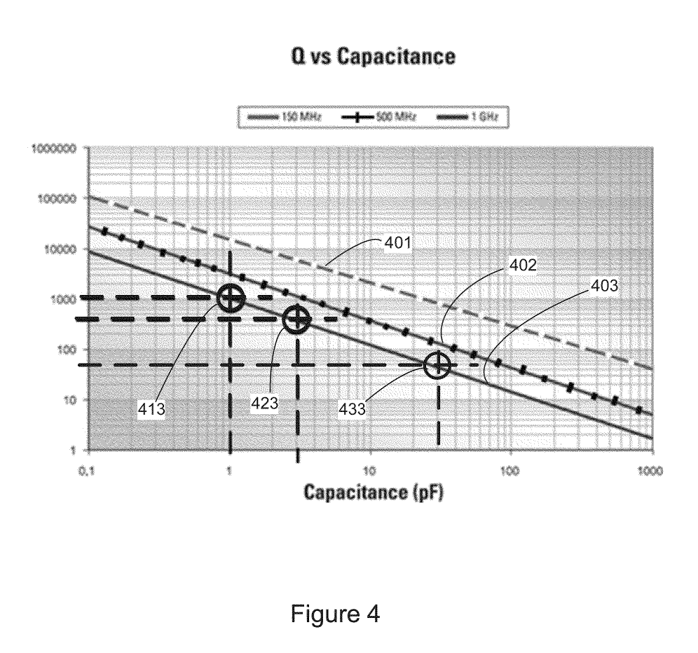

The benefit of the above described solution may be better understood by referring to FIG. 4, which illustrates typical Q as a function of capacitance for a varactor of the type identified hereinabove. More particularly, plot 401 illustrates Q as a function of capacitance for a hyperabrupt junction gallium arsenide diode individual varactor operating at 150 MHz; plot 402 illustrates Q as a function of capacitance for the varactor operating at 500 MHz; and plot 403 illustrates Q as a function of capacitance for the individual varactor operating at 1 GHz. It may be observed that, for a given frequency, Q of such varactors decreases as capacitance increases. More particularly, it may be observed, referring still to FIG. 4, that for a varactor operating at 1 GHz, the Q factor for a 3 pF device is approximately 400, illustrated at point 423, whereas the Q factor for a 1 pF device is approximately 1000, illustrated at point 413.

Thus, for the example above, where capacitive element 310 is required to provide a nominal capacitance of 3 pF, three parallel 1 pF varactors, each having a Q of 1,000, may be advantageously employed, instead of a single 3 pF varactor, which would be expected to have a Q of 400.

As a further example, referring still to FIG. 4, it may be observed, that for a varactor operating at 1 GHz, the Q factor for a 12 pF device is approximately 40, illustrated at point 433, whereas the Q factor for a 3 pF device is approximately 400, illustrated at point 423.

Thus, where capacitive element 310 is required to provide a nominal capacitance of 12 pF, four parallel 3 pF varactors, each having a Q of 400, may be advantageously employed, instead of a single 12 pF varactor, which would be expected to have a Q of 40.

Thus, a resonant circuit having a capacitance with improved Q factor has been disclosed. The foregoing merely illustrates principles of the invention. It will be appreciated that those skilled in the art will be able to devise numerous systems and methods which, although not explicitly shown or described herein, embody said principles of the invention and are thus within the spirit and scope of the invention as defined by the following claims.

What is claimed is:

1. A resonant circuit, configured to operate at a resonant frequency, and comprising:
a first arrangement providing a first equivalent capacitance ‘C’ and a second arrangement providing a first inductance; the first arrangement comprising:
a quantity of ‘n’ capacitive elements connected in parallel, n being at least two, each of the n capacitive elements having a nominal capacitance approximately equal to C/n.

2. The resonant circuit of claim 1, wherein at least one of the n capacitive elements has a fixed capacitance.

3. The resonant circuit of claim 2, wherein at least one of the n capacitive elements has a variable capacitance.

4. The resonant circuit of claim 1, wherein the resonant frequency is at least 1 GHz, the first equivalent capacitance is at least 3 pF, and a composite Q factor of the first arrangement is greater than 800.

5. The resonant circuit of claim 4, wherein the first arrangement is connected in parallel with the second arrangement.

6. The resonant circuit of claim 4, wherein the first arrangement is connected in series with the second arrangement.

7. The resonant circuit of claim 4, wherein at least one capacitive element is a varactor.

8. The resonant circuit of claim 1, wherein the resonant frequency is at least 1 GHz, the first equivalent capacitance is at least 12 pF, and a composite Q factor of the first arrangement is greater than 300.

9. The resonant circuit of claim 1, wherein a single capacitive element having a capacitance of C exhibits a Q factor equal to ‘Q1’, the composite Q factor of the first arrangement is equal to ‘Q2’, and Q2 is substantially higher than Q1.

10. A resonant circuit, configured to operate at a resonant frequency, and comprising:
a first arrangement providing a first capacitance and a second arrangement providing a first inductance; wherein the resonant frequency is at least 1 GHz, the first capacitance is at least 3 pF, and a composite Q factor of the first arrangement is greater than 800.

11. The resonant circuit of claim 10, the first arrangement comprising:
a quantity of ‘n’ capacitive elements connected in parallel, n being at least two, each of the n capacitive elements having a nominal capacitance approximately equal to C/n.

12. The resonant circuit of claim 11, wherein at least one of the n capacitive elements has a fixed capacitance.

13. The resonant circuit of claim 12, wherein at least one of the n capacitive elements has a variable capacitance.

14. The resonant circuit of claim 11, wherein the resonant frequency is at least 1 GHz, the first equivalent capacitance is at least 3 pF, and a composite Q factor of the first arrangement is greater than 800.

15. The resonant circuit of claim 11, wherein the first arrangement is connected in parallel with the second arrangement.

16. The resonant circuit of claim 11, wherein the first arrangement is connected in series with the second arrangement.

17. The resonant circuit of claim 11, wherein at least one capacitive element is a varactor.

18. The resonant circuit of claim 11, wherein the resonant frequency is at least 1 GHz, the first equivalent capacitance is at least 12 pF, and a composite Q factor of the first arrangement is greater than 300.

19. The resonant circuit of claim 11, wherein a single capacitive element having a capacitance of C exhibits a Q factor equal to ‘Q1’, the composite Q factor of the first arrangement is equal to ‘Q2’, and Q2 is substantially higher than Q1.

20. A resonant circuit, configured to operate at a resonant frequency, and comprising:
a first arrangement providing a first equivalent capacitance ‘C’ and a second arrangement providing a first inductance; the first arrangement comprising:
a quantity of ‘n’ capacitive elements connected in parallel, n being at least two, each of the n capacitive elements having a nominal capacitance approximately equal to C/n; wherein:
a single capacitive element having a capacitance of C exhibits a Q factor equal to ‘Q1’, the composite Q factor of the first arrangement is equal to ‘Q2’, and Q2 is substantially higher than Q1.
